(19) United States
(12) Patent Application Publication
(10) Pub. No.: US 2008/0159445 A1
(43) Pub. Date: Jul. 3, 2008

(54) VITERBI-INPUT AUTO SCALING FOR PACKET-BASED SYSTEM

(76) Inventor: Stephan ten Brink, Irvine, CA (US)

Correspondence Address: CHRISTIE, PARKER & HALE, LLP, PO BOX 7068, PASADENA, CA, 91109-7068, US

(21) Appl. No.: 11/962,028

(22) Filed: Dec. 20, 2007

Related U.S. Application Data
(60) Provisional application No. 60/871,102, filed on Dec. 20, 2006.

(51) Int. Cl. H03D 1/00; H04L 27/06; G06F 3/033

(52) U.S. Cl. 375/340; 375/341; 455/130

(57) ABSTRACT

A receiver in a wireless communication system scales received information to allow for improved decoder performance after bit reduction of the information. Mean values of the received information may be used to scale the information, with a plurality of mean values determined, each in a different way. Depending on types of spreading applied to the information by a transmitter, as indicated by a rate signal, different ones of the mean values are used for scaling. Preferably the mean values are determined using channel compensated information.

### CROSS-REFERENCE TO RELATED APPLICATION(S)

This application claims the benefit of the filing date of U.S. Provisional Patent Application No. 60/871,102, filed Dec. 20, 2006, the disclosure of which is incorporated by reference herein.

### BACKGROUND

The present invention relates generally to packet based communication systems, and more particularly to scaling of inputs to a decoder in a packet based wireless communication system.

Communication systems generally transmit information from a transmitter to a receiver over a medium. The transmitted information is subject to corruption or degradation due to a variety of causes. The transmitter circuitry may introduce noise, the transmission medium may alter the information and reflections or energy from interfering sources may also be present at the receiver, and the receiver may introduce noise or otherwise fail to properly recapture the data.

Many systems therefore attempt to adjust operation so as to account for these and other possible sources of error. Redundant information is often added to data transmissions, for example using error correction coding, allowing for correction of some errors by a decoder of the receiver. Receiver circuitry for decoding encoded data, however, may be power and space intensive, increasing receiver cost, increasing receiver power usage, and also possibly increasing receiver failure rates.

Soft bits are often used in decoding schemes to improve decoder correction capabilities. Reducing the number of soft bits used may decrease decoder complexity and power requirements, with the soft bits possibly scaled before reducing the number of bits used. Inappropriate scaling of soft bits, however, may increase degradation of received data. Further, some communication systems additionally transmit data over different frequencies possibly using different spreading methods. The use of different frequencies and different spreading methods may further complicate decoder input scaling considerations.

### BRIEF SUMMARY OF THE INVENTION

The present invention provides for scaling of information prior to reducing bits used by a decoder, for example a soft decision decoder. In one aspect the invention provides a method of scaling decoder inputs performed by a receiver in an ultrawideband (UWB) communication system, comprising determining a plurality of values using received information; determining a data rate for further received information; selecting a one of the plurality of values based on the data rate; scaling a representation of the further received information using the one of the plurality of values; reducing in number bits used to represent the scaled representation of the further received information; and decoding received information using the reduced number of bits.

In another aspect the invention provides a method of scaling soft bit decision decoder inputs, comprising: receiving complex symbols; determining a mean value for the complex symbols; time combining the complex symbols; determining a mean value for the time combined complex symbols; frequency combining the time combined complex symbols; determining a mean value for the frequency and time combined complex symbols; receiving an indication of a data rate for further received information; scaling a representation of the further received information using one of the mean value for the complex symbols, the mean value for the time combined complex symbols, or the mean value of the frequency and time combined complex symbols based on the indication of the data rate for the further received information; reducing the number of bits used for the scaled representation of the further received information; and providing the reduced number of bits to a decoder.

In yet another aspect the invention provides a receiver for an wireless communication system, comprising: an RF portion including amplification and downconversion circuitry; an analog-to-digital converter for converting signals provided by the RF portion to digital signals; a Fast Fourier Transform block configured to transform samples of the digital signals to symbols in the frequency domain; a demapper configured to generate multiple bit symbols based on the symbols in the frequency domain; mean value computation circuitry configured to generate mean values of the symbols in a plurality of ways; and a scaler configured to scale the multiple bit symbols using a rate selectable one of the mean values.

These and other aspects are more fully comprehended upon consideration of this disclosure.

### BRIEF DESCRIPTION OF THE DRAWINGS

FIG. 1 is a block diagram of a receiver in accordance with aspects of the invention;

FIG. 2 is a block diagram of a scaler block for a receiver in accordance with aspects of the invention;

FIG. 3 is a timing chart for an example packet;

FIG. 4 is a block diagram of example circuitry including mean value computation circuitry in accordance with aspects of the invention;

FIG. 5 illustrates an example of time repetition and frequency repetition;

FIG. 6 illustrates further details of a packet;

FIG. 7 is a block diagram of a receiver in accordance with aspects of the invention; and

FIG. 8 is a block diagram of a transmitter in accordance with aspects of the invention.

### DETAILED DESCRIPTION

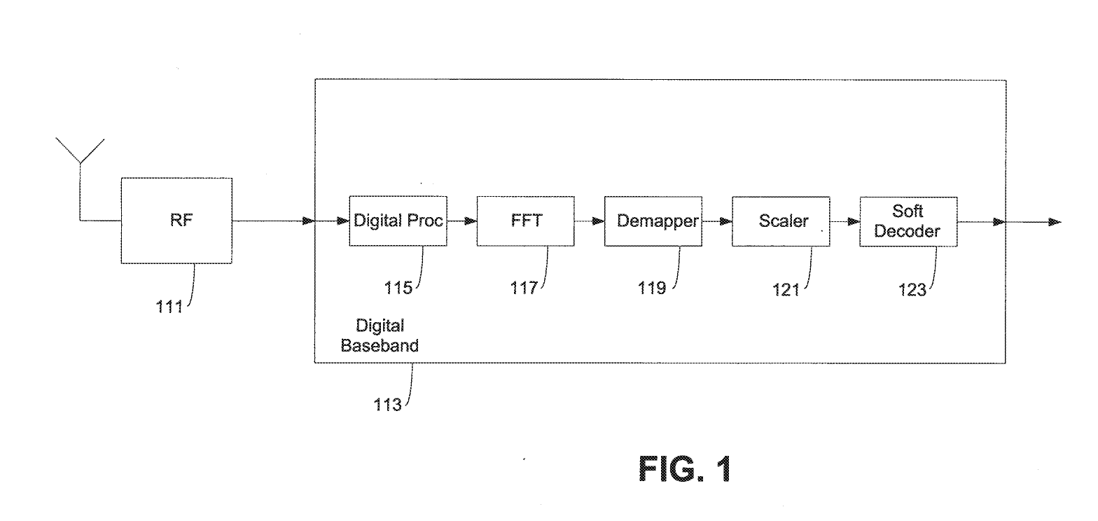

FIG. 1 is a block diagram of a receiver in accordance with aspects of the invention. The receiver may be, for example, a receiver for an orthogonal frequency division multiplexing (OFDM) system, such as in an OFDM ultrawideband (UWB) system. An RF portion 811 of the receiver receives signals via an antenna. Generally the RF portion comprises analog circuitry, and amplifies and downconverts received radio frequency signals. The received signals are analog-to-digital (A/D) converted by an A/D converter (ADC), with the ADC placed either within the RF block or within a digital baseband 813 portion of the receiver.

The digital baseband portion digitally processes received signals. In a digital processing block 815 operations on the received digital signal are performed. Operations generally include packet detection, frame synchronization, automatic gain control, and other operations. The processed signal is transformed to the frequency domain by an FFT block 817. The frequency domain signal is demapped by demapper 819. The demapper output is scaled by a scaler 821. The scaler includes circuitry for scaling the output of the demapper for use in soft decoding. In some embodiments the scaler includes circuitry for determining mean values of received information, with the demapper output scaled using the mean values. In most embodiments, however, the demapper block includes circuitry to determine the mean values, or alternatively the mean value computation circuitry may be located elsewhere in the digital baseband portion of the receiver.

The mean values may be mean absolute values of received symbols, for example of the complex symbols provided by the FFT block. In some embodiments mean values may be determined using different methods, for example by summing over different numbers of subcarriers and/or different number of symbols, with the mean value selected for use based on a predefined criteria, for example payload data rate. In addition, in some embodiments mean value determinations are made using channel compensated symbols of a preamble, with scaling performed for payload data only.

A soft decoder 823 decodes the scaled demapper output. The soft decoder generally includes circuitry for performing decoding, such as Viterbi decoding. The decoded information is then provided to further components, for example, a media access controller (MAC). In some embodiments the soft decoder reduces the number of bits used to represent the scaled demapper output prior to decoding. In general, however, received information is also interleaved and possibly punctured, and deinterleaving may be performed by deinterleaving circuitry and depuncturing may be performed by a depuncture block, which may be part of the soft decoder block, or separate blocks prior to the soft decoder block. In such cases bit reduction is generally performed prior to deinterleaving and depuncturing.

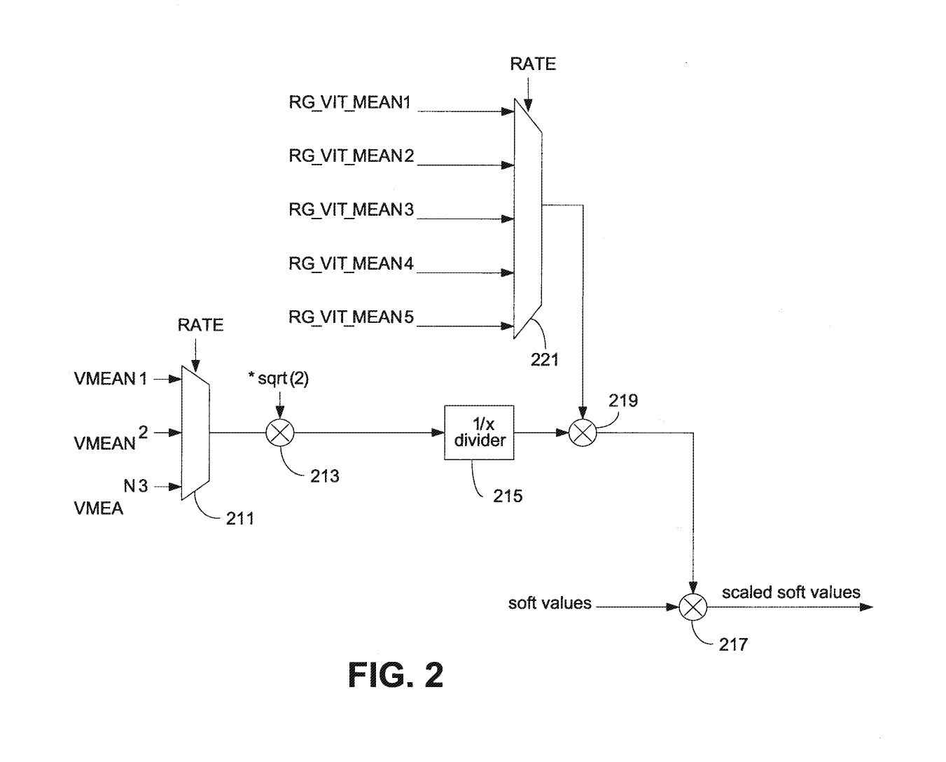

FIG. 2 is a block diagram of an embodiment of a scaler block for a receiver. A plurality of mean values are received by a multiplexer 201. The multiplexer selects one of the mean values based on a rate signal. The rate signal provides an indication of a data rate for received information. The mean values are means values of symbols received by the receiver, with the mean values calculated in different ways.

In one embodiment one of the mean values, for example VMEAN1, is determined using information from a first number of subcarriers and a first number of symbols. A second mean value, for example VMEAN2, is determined using information from the same number of subcarriers as used for VMEAN1, but over fewer symbols, with for example the symbols being combined over time. A third mean value, for example VMEAN3, may be determined over a fewer number of subcarriers and a fewer number of symbols, with for example the subcarriers having been subject to combination in frequency.

The selected mean value is provided to a square root block 213, which determines a square root value of the selected mean value. The square root of the selected mean value is then inverted by a 1/X divider 215. In some embodiments the inverse of the square root is used to scale the demapped soft values in a multiplier block 217, with the scaled soft values then subject to further processing. As illustrated in FIG. 2, however, the inverse of the square root of the selected mean value is multiplied by a constant in a multiplier block 219. Preferably the constant by which the inverse of the square root of the selected mean value is multiplied is a predetermined value stored, for example, in a register of the receiver.

As shown in FIG. 2, the constant is selected from one of a plurality of constants. Thus, a plurality of constants are provided to a multiplexer 221. A particular constant of the plurality of constants is selected using the rate signal. As illustrated in FIG. 2, five different constants are provided to the multiplexer, with a different constant selected based on the data rate. In some embodiments a first constant is selected if the data rate is between 53.3 and 80 MHz. A secondary constant may be selected if the data rate is between 106.7 and 200 MHz. A third constant may be selected if the data rate is between 320 and 400 MHz. A fourth constant may be selected if the data rate is between 480 and 512 MHz. Finally, a fifth constant may be selected if the data rate is between 640 and 1,024 MHz. In one embodiment the first constant is equal to 8, the second constant is also equal to 8, the third constant is equal to 12, the fourth constant is equal to 24, and the fifth constant is equal to 28.

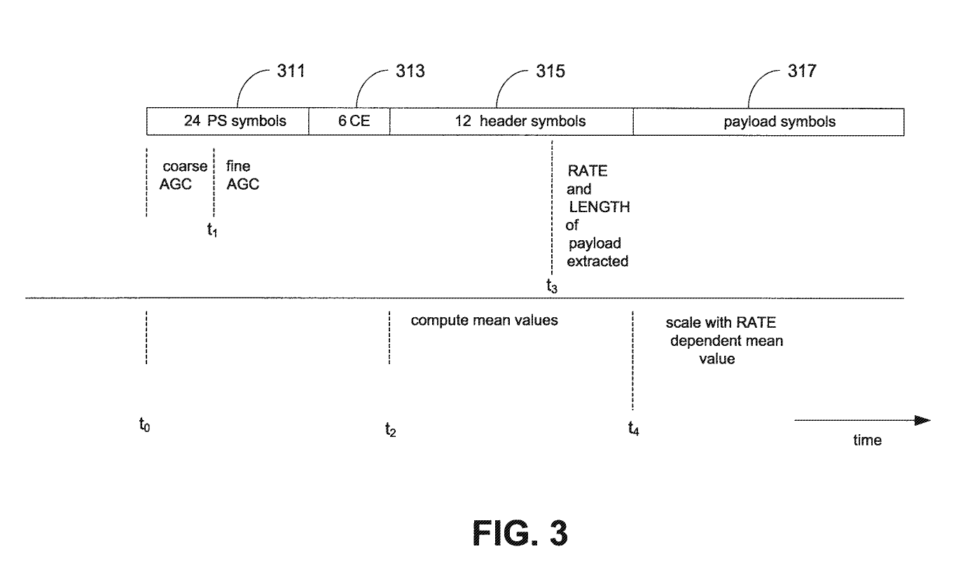

In some embodiments mean value scaling of decoder inputs is only performed for a payload portion of a packet, and in some embodiments the mean values are determined only once channel compensation information is available to be performed on received symbols. FIG. 3 shows a timing chart for an example packet. The packet includes 24 packet sequence symbols 311. The packet sequence symbols are generally used to detect packets and determine symbol and packet timing. The 24 packet sequence symbols are followed by 6 channel estimate symbols 313. The channel estimate symbols may be used to determine an estimate of channel effects, which allows the receiver to compensate for the channel effects. As illustrated in FIG. 3, 12 header symbols 315 follow the channel estimate symbols. The header symbols generally include information relating to the packet, for example the data rate for the payload and the length of the payload. As also is illustrated in FIG. 3, payload symbols 317 follow the header symbols. Varying numbers of payload symbols may be provided, depending on the length of the payload.

As shown in FIG. 3, automatic gain control is generally performed upon receiving packets at time tₒ. A fine automatic gain control may also be performed on received symbols, with the fine automatic gain control determined in some embodiments by a digital baseband portion of the receiver, with fine automatic gain control generally taking effect during receipt of packet sequence symbols at time t₁. Mean values for received symbols are calculated at time t₂, which is after receipt by the receiver of the channel estimate symbols. Preferably computation of mean values is for symbols for which channel compensation has been performed. At time t₃ rate information for the payload is available. At time t₄ payload symbols are received, with a mean value selected for scaling of the payload symbols dependent on the rate. for the payload

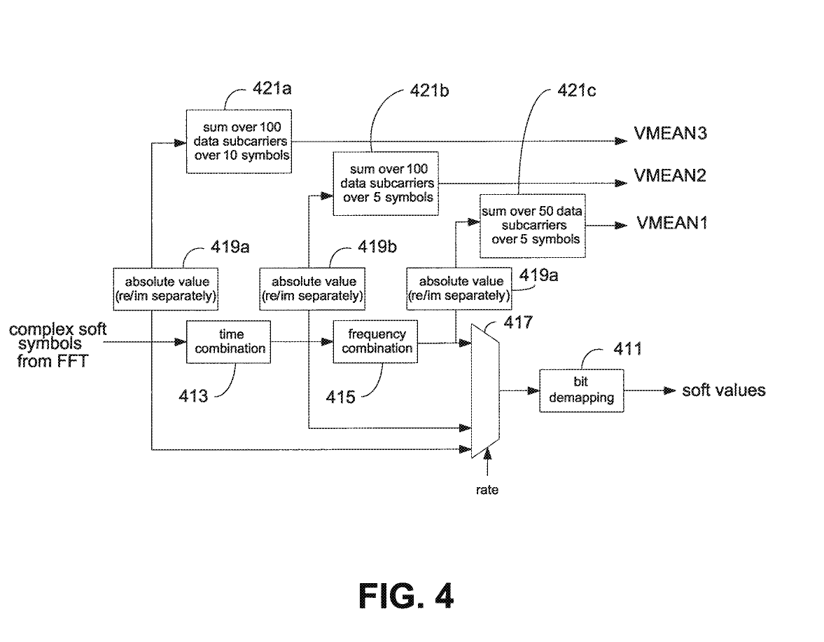

FIG. 4 is a block diagram for circuitry including mean value computation circuitry. As illustrated in FIG. 4, the circuitry is implemented as part of a demapper and a demapper block is included in the block diagram of FIG. 4. Accordingly, the block diagram of FIG. 4 may be considered a block diagram of a demapper block including mean value computation circuitry.

The demapper block receives complex soft symbols generated by a fast Fourier transform (FFT) block. A bit demapper 411 performs bit demapping of the complex soft symbols. The bit demapper demodulates or demaps a symbol, in a QPSK format for example, to bit values. In some embodiments symbols are modulated or mapped by a transmitter using one, some, or all of a QPSK scheme, a DCM scheme or a 16-QAM scheme, with the demapper including appropriate circuitry for demodulating or demapping of the symbols.

In some embodiments, usually depending on desired data rate, symbols on different subcarriers may be coherently combined at the receiver, and repetitive symbols in time may be similarly combined, for example to compensate for fading effects at different frequencies. Table 1 shows the use of time repetition and frequency repetition for different data rates in an example UWB system.

TABLE 1

| | | | Time | Frequency repetition |
|---|---|---|---|---|
| Data | | | repetition | (“complex conjugate |
| rate | modu- | | (“time | symmetric |
| (Mbps) | lation | code rate | spreading”) | spreading”) |
| 53.3 | QPSK | 1/3 | yes | yes |
| 80 | QPSK | 1/2 | yes | yes |
| 106.7 | QPSK | 1/3 | yes | no |
| 160 | QPSK | 1/2 | yes | no |
| 200 | QPSK | 5/8 | yes | no |
| 320 | DCM | 1/2 | no | no |
| 400 | DCM | 5/8 | no | no |
| 480 | DCM | 3/4 | no | no |
| 512 | DCM | 4/5 | no | no |
| 640 | 16-QAM | 1/2 | no | no |
| 800 | 16-QAM | 5/8 | no | no |
| 960 | 16-QAM | 3/4 | no | no |
| 1024 | 16-QAM | 4.5 | no | no |

Table 1 shows that time repetition is used for data rates from 53.3 megabits per second (Mbps) to 200 Mbps. Table 1 shows that frequency repetition is additionally used for data rates of 53.3 Mbps and 80 Mbps.

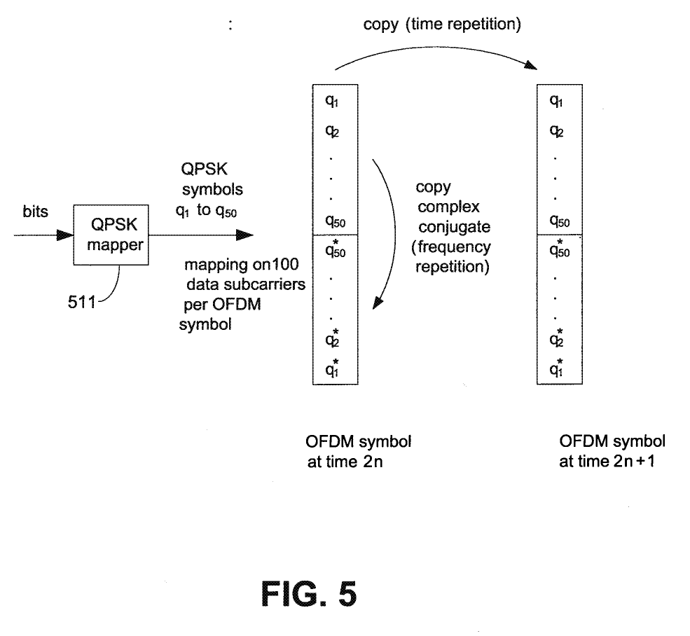

FIG. 5 illustrates an example of time repetition and frequency repetition by a transmitter using QPSK mapping, with the QPSK mapping forming a symbol with 50 elements q₁ to q₅₀ intended for transmission over 50 subcarriers. Bits for mapping are provided to a QPSK mapper 511, which sometimes may be referred to as a modulator. The QPSK mapper maps bits to QPSK symbols q₁ to q₅₀. The symbols q₁ to q₅₀ are to be transmitted on different subcarrier frequencies. Frequency repetition is provided by forming a further 50 symbols, with the further 50 symbols complex conjugate of the symbols q₁ to q₅₀. The 50 further symbols are to be transmitted on a further 50 subcarriers.

Time repetition is provided by copying the OFDM symbol to a second time period, for example immediately following the first time period, or some other time period dependent on a frequency hopping pattern, for example such that the repeated UFDM symbol is transmitted on a different frequency subband. In many embodiments repetitive transmission of symbols provides further frequency diversity as many systems use time frequency hopping.

Table 2 shows an example of time frequency hopping used in some embodiments of the invention.

TABLE 2

| TFC | subband nb | | | | | |
|---|---|---|---|---|---|---|
| number | time n = 0 | n = 1 | n = 2 | n = 3 | n = 4 | n = 5 |
| 1 | 1 | 2 | 3 | 1 | 2 | 3 |
| 2 | 1 | 3 | 2 | 1 | 3 | 2 |
| 3 | 1 | 1 | 2 | 2 | 3 | 3 |
| 4 | 1 | 1 | 3 | 3 | 2 | 2 |
| 5 | 1 | 1 | 1 | 1 | 1 | 1 |
| 6 | 2 | 2 | 2 | 2 | 2 | 2 |
| 7 | 3 | 3 | 3 | 3 | 3 | 3 |
| 8 | 1 | 2 | 1 | 2 | 1 | 2 |
| 9 | 1 | 3 | 1 | 3 | 1 | 3 |
| 10 | 2 | 3 | 2 | 3 | 2 | 3 |

Table 2 shows 10 frequency hopping patterns over time, with each pattern indicated by a TFC number. For example, for TFC 1 transmission occurs over a first subband of frequencies at time n=0. At time n=1 transmissions occur over a second subband of frequencies. At time n=2 transmissions occur over a third subband of frequencies, with the pattern thereafter repeating. Accordingly, for many TFCs, symbols repeated in time are transmitted at different frequencies, providing frequency diversity.

Thus, it may be seen that in some embodiments transmitted symbols are either subjected to time repetition and frequency repetition, only time repetition, or neither time repetition or frequency repetition. Accordingly, returning to FIG. 4, the demapper block includes a time combination block 413 which receives the complex soft symbols. The time combination block includes circuitry for coherently combining symbols from different time periods. The demapper block also includes a frequency combination block 415. The frequency combination block performs coherent frequency combination of the time combined symbols. The complex soft symbols, the time combined soft symbols, and the time and frequency combined soft symbols are all provided to a multiplexer 417. A rate indication signal serves as a selector signal for the multiplexer, with either the soft symbols, the time combined soft symbols, or the time and frequency combined soft symbols provided to the demapper for demapping.

The mean values may differ dependent on whether time and frequency combination have been performed, only time combination has been performed, or neither time or frequency combinations have been performed. Accordingly, the block diagram of FIG. 4 includes three absolute value blocks 419a-c. The absolute value block 419a determines the absolute value separately for the real and imaginary parts, of the complex soft symbols. The absolute value block 419b determines the absolute values, with the real and imaginary parts determined separately, or the time combined soft symbols provided by time combination block 413. The absolute value block 419c determines the absolute value, with the real and imaginary portions calculated separately, for the time and frequency combined soft symbols provided by frequency combination block 415.

A mean value calculation block 421a receives the absolute values determined by the absolute value block 419a, and determines a mean value of the complex soft symbols. In one embodiment an OFDM symbol is transmitted over 100 data subcarriers, and the mean value is calculated over the 100 data subcarriers. Similarly, in one embodiment the header portion of a packet includes 12 symbols after channel compensation is available, accordingly 10 symbols are used for the determination of the mean value so as to allow for a timing buffer before beginning processing of a payload portion of a packet.

A mean value calculation block 421b similarly receives absolute values from the absolute value block 419b. As an absolute value block 419b is determining absolute values for symbols which have been combined in time, the mean value calculation block 421b determines mean values over 100 data subcarriers, but only 5 symbols in view of the 12 available symbols in the packet header after channel compensation begins and in view of the combination of symbols over time.

Also similarly, a mean value calculation block 421c receives absolute values from the absolute value block 419c. The absolute value block 419c determines absolute values of symbols which have been combined in time and combined in frequency. Accordingly, the mean value computation block 421c determines mean values over 50 data subcarriers over 5 symbols.

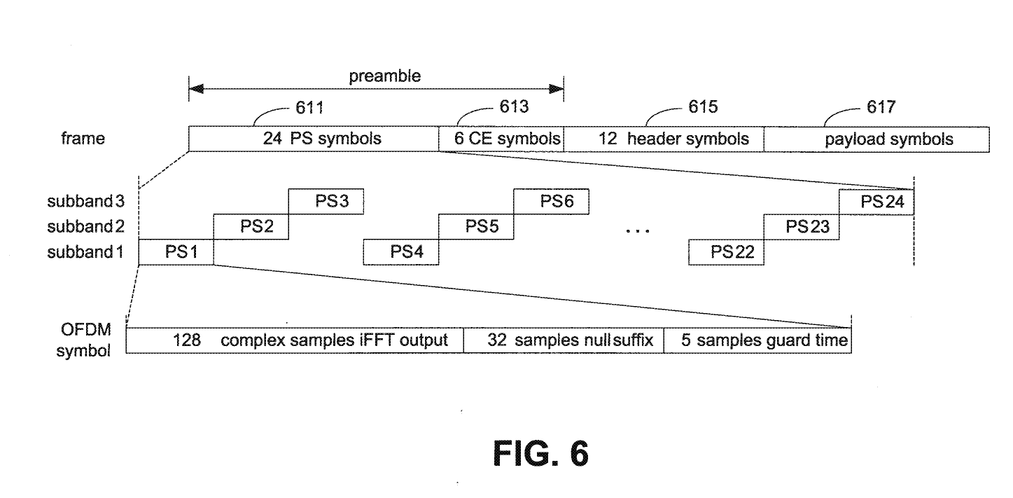

For completeness, FIG. 6 illustrates further details of a packet. The packet is organized in a frame with 24 packet sequence symbols 611, 6 channel estimation symbols 613, 12 header symbols 615, and payload symbols 617. The symbols are provided over a frequency hopping pattern, which is illustrated for the packet sequence symbols. A first packet sequence symbol PS1 is transmitted over a first band subband of frequencies, subband 1. A second packet sequence symbol PS2 is transmitted over a second subband of frequencies, subband 2. A third packet sequence symbol PS3 is transmitted over a third subband of frequencies, subband 3. The sequence is then repeated for further symbols.

Also, as shown in FIG. 6, each symbol is an OFDM symbol, an example of which is shown for packet sequence symbol PS1. The example OFDM symbol includes 128 complex samples formed generally by an inverse fast Fourier transform (iFFT) block. The example OFDM symbol also includes 32 null samples post pended to the 128 complex samples. Further, 5 samples are provides as guard time to allow for frequency hopping, for example.

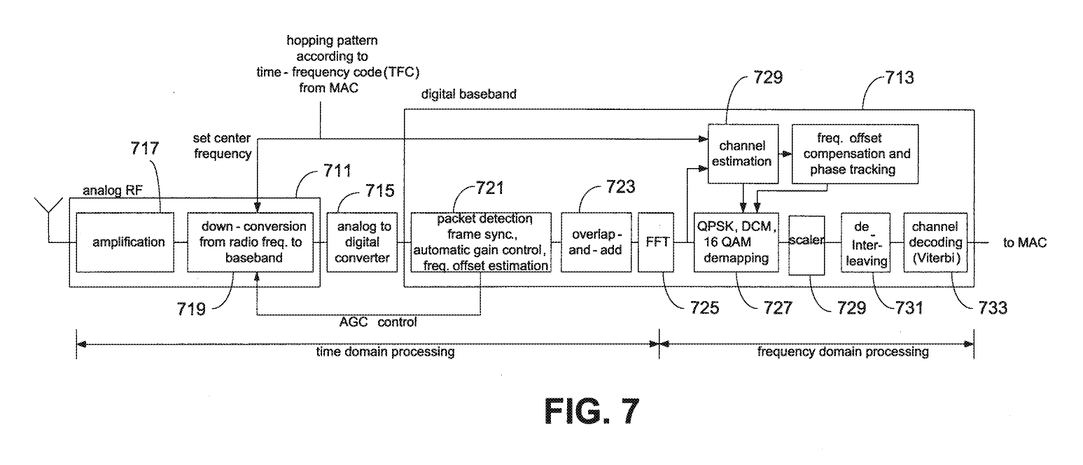

FIG. 7 shows a further embodiment of a receiver in accordance with aspects of the invention. The receiver includes an analog RF portion 711 and a digital baseband portion 713. An analog to digital converter 715 is shown between the analog RF portion and the digital baseband portion. Signals are received by an antenna and amplified by amplification circuitry 717 in the RF portion. The amplified signals are downconverted from radio frequency to baseband by downconversion circuitry 719. The downconversion is generally performed in accordance with a time frequency code provided by for example a MAC, (not shown) and the downconversion circuitry often additionally includes further amplification circuitry. The RF portion generally also includes automatic gain control (AGC) circuitry. The downconversion and amplification circuitry may also provide additional automatic gain control, in addition to automatic gain control provided solely by the analog portion, under the direction of a AGC control signal provided by the digital baseband portion.

The analog baseband signal is converted from analog to digital by the analog-to-digital converter.

A digital processing block 721 of the digital baseband includes circuitry for performing packet detection, frame synchronization, fine automatic gain control processing, and frequency offset estimation. As illustrated in FIG. 7, received samples are subject to an overlap and add process, on a symbol by symbol basis, by an overlap and add block 723, which may for example overlap and add portions of the expected null symbols to improve performance of an FFT block. An FFT block 725 transforms the signals from the time domain to the frequency domain. The transformed signals are provided to a demapper block 727 and also to a channel estimation block 729. The channel estimation block uses the channel estimation symbols, which are generally of predefined values, to determine channel effects. Channel compensation based on the determined channel effects may occur within the demapper block although in many embodiments channel compensation may be otherwise performed. Channel estimation information is also provided to a frequency offset compensation and phase tracking block 713 that additionally provides for frequency and phase compensation.

The demapper demaps the received symbols. In many embodiments the demapper also performs coherent time combining and coherent frequency combining, which may be dependent on selected data rates. A scaler 729 scales the demapped symbols. The scaled demapped symbols are deinterleaved by a deinterleaver block 731, and then decoded by a decoder 733. As illustrated the decoder is a Viterbi decoder. The information is then provided to the MAC.

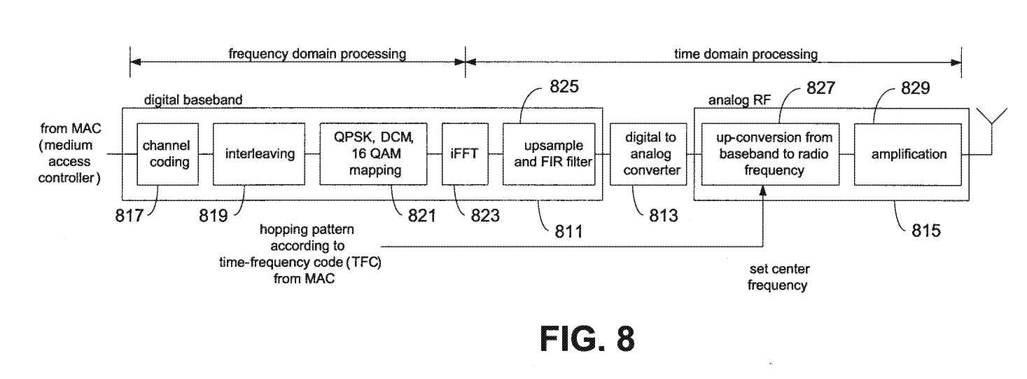

FIG. 8 is a block diagram of a transmitter in accordance with aspects of the invention. The transmitter includes a digital baseband portion 811, a digital-to-analog converter 813, and an analog RF portion 815. A MAC (not shown) provides information for transmission. A channel coding block 817 encodes the information. The encoded information is interleaved by an interleaver block 819. The encoded interleaved information is mapped by a mapping block 821, and then transformed from the frequency domain to the time domain by an iFFT block 823. As shown in FIG. 8, the symbols provided by the iFFT block are upsampled and processed by a finite impulse response (FIR) filter block 825. The information is then digital to analog converted by the digital-to-analog converter and provided to the analog RF portion. An upconverter 827 of the analog RF portion upconverts the information from baseband to radio frequency, generally according to a hopping pattern provided by the MAC. The upconverted information is then amplified by an amplifier 829 and transmitted over a n antenna.

Accordingly, methods and apparatus for scaling information for a decoder have been discussed. Although the invention has been described in certain specific embodiments, it should be recognized that it may be practiced otherwise than as specifically described. Accordingly, the invention should be considered the claims and their insubstantial variations supported by this disclosure.

What is claimed is:

1. A method of scaling decoder inputs performed by a receiver in an ultrawideband (UWB) communication system, comprising:
determining a plurality of values using received information;
determining a data rate for further received information;
selecting a one of the plurality of values based on the data rate;
scaling a representation of the further received information using the one of the plurality of values;
reducing in number bits used to represent the scaled representation of the further received information; and
decoding received information using the reduced number of bits.

2. The method of claim 1 wherein at least one of the plurality of values is a mean absolute value of complex symbols formed using the received information.

3. The method of claim 2 wherein at least one of the mean absolute values is a mean absolute value of the complex symbols after time combination.

4. The method of claim 3 wherein at least one of the mean absolute values is a mean absolute values of the complex symbols after time and frequency combination.

5. The method of claim 1 wherein the received information is of a header in a packet.

6. The method of claim 5 wherein the further received information is of a payload of a packet.

7. The method of claim 6 wherein the header includes rate information for the further received information.

8. The method of claim 1 wherein the received information has been channel compensated.

9. The method of claim 8 wherein the channel compensation has been performed based on channel estimates provided as part of the packet.

10. The method of claim 1 wherein scaling the representation of the further received information using the one of the plurality of values comprises scaling the representation of the further received information by a dividing the representation of the further received information by a square root of the one of the plurality of values.

11. The method of claim 10 wherein scaling the representation of the further received information using the one of the plurality of values further comprises multiplying the representation of the further received information by a data rate dependent constant.

12. The method of claim 11 wherein the data rate dependent constant is selected from a plurality of stored constants.

13. A method of scaling soft bit decision decoder inputs, comprising:
receiving complex symbols;
determining a mean value for the complex symbols;
time combining the complex symbols;
determining a mean value for the time combined complex symbols;
frequency combining the time combined complex symbols;
determining a mean value for the frequency and time combined complex symbols;
receiving an indication of a data rate for further received information;
scaling a representation of the further received information using one of the mean value for the complex symbols, the mean value for the time combined complex symbols, or the mean value of the frequency and time combined complex symbols based on the indication of the data rate for the further received information;
reducing the number of bits used for the scaled representation of the further received information; and
providing the reduced number of bits to a decoder.

14. The method of claim 13 wherein the complex symbols and the further received information are part of a packet, the complex symbols are based on channel compensated received information received after receipt of channel estimates provided with the packet, and the further received information comprises a payload of the packet.

15. A receiver for an wireless communication system, comprising:
an RF portion including amplification and downconversion circuitry;
an analog-to-digital converter for converting signals provided by the RF portion to digital signals;
a Fast Fourier Transform block configured to transform samples of the digital signals to symbols in the frequency domain;
a demapper configured to generate multiple bit symbols based on the symbols in the frequency domain;
mean value computation circuitry configured to generate mean values of the symbols in a plurality of ways; and
a scaler configured to scale the multiple bit symbols using a rate selectable one of the mean values.

16. The receiver of claim 15 wherein the mean value computation circuitry is configured to generate mean values of the symbols by generating mean values of the symbols, by generating mean values of the symbols after time combination, and by generating mean values of the symbols after time and frequency combination.
